(19) United States
(12) Patent Application Publication
(10) Pub. No.: US 2012/0286259 A1
(43) Pub. Date: Nov. 15, 2012

(54) DISPLAY SUBSTRATE AND METHOD OF MANUFACTURING THE SAME

(75) Inventors: Jae-Woo PARK, Seongnam-si (KR); Dong-Hoon LEE, Seoul (KR); Sung-Haeng CHO, Chungbuk (KR); Woo-Geun LEE, Yongin-si (KR); Kap-Soo YOON, Seoul (KR)

(73) Assignee: SAMSUNG ELECTRONICS CO., LTD., Suwon-si (KR)

(21) Appl. No.: 13/431,448

(22) Filed: Mar. 27, 2012

(30) Foreign Application Priority Data
May 12, 2011 (KR) 10-2011-0044397

(51) Int. Cl. H01L 29/786; H01L 21/44

(52) U.S. Cl. 257/43; 438/104; 257/E29.296; 257/E21.476

(57) ABSTRACT

Exemplary embodiments of the present invention provide a display substrate including a gate electrode, an oxide semiconductor pattern, a source electrode, a drain electrode, and an etch stop pattern. The gate electrode may be disposed on a base substrate. The oxide semiconductor pattern may be disposed over the gate electrode. The source electrode may be disposed on the oxide semiconductor pattern. The drain electrode may be disposed on the oxide semiconductor pattern and spaced apart from the source electrode. The etch stop pattern may be disposed over the gate electrode, the etch stop pattern may be overlapping a space between the source electrode and the drain electrode and may include a metal oxide. The reliability of the display substrate may, therefore, be improved.

### CROSS REFERENCE TO RELATED APPLICATION

This application claims priority from and the benefit of Korean Patent Application No. 10-2011-0044397, filed on May 12, 2011, which is hereby incorporated by reference for all purposes as if fully set forth herein.

### BACKGROUND OF THE INVENTION

1. Field of the Invention

Exemplary embodiments of the present invention relate to a display substrate and a method of manufacturing the display substrate, wherein the display substrate includes an oxide semiconductor.

2. Discussion of the Background

Recently, a method of manufacturing a display substrate, including an oxide semiconductor, has been developed. The display substrate, including the oxide semiconductor, includes an etch stop pattern such that a portion of the oxide semiconductor may not be patterned when a data metal pattern is formed.

Generally, the oxide semiconductor is deposited through a sputter deposition method, and an etch stop layer for forming the etch stop pattern is deposited through a chemical vapor deposition (CVD) method. Thus, the display substrate needs to be transferred from a first chamber for depositing the oxide semiconductor to a second chamber for depositing the etch stop layer. However, when the display substrate is transferred from the first chamber to the second chamber, the oxide semiconductor deposited in the first chamber may be exposed to a contaminated environment.

In addition, according to conventional manufacturing methods, at least 6 masks are used to form a gate metal pattern, an oxide semiconductor pattern, an etch stop pattern, a data metal pattern, a contact hole and a pixel electrode of the display substrate.

### SUMMARY OF THE INVENTION

Exemplary embodiments of the present invention provide a display substrate with greater reliability and reduced manufacturing costs.

Additional features of the invention will be set forth in the description which follows, and in part will be apparent from the description, or may be learned by practice of the invention.

Exemplary embodiments of the present invention disclose a display substrate including a gate electrode disposed on a base substrate, an oxide semiconductor pattern disposed over the gate electrode, a source electrode disposed on the oxide semiconductor pattern, a drain electrode disposed on the oxide semiconductor pattern and spaced apart from the source electrode, and an etch stop pattern including a metal oxide. The etch stop pattern is disposed on the oxide semiconductor pattern. At least a part of the etch stop pattern is disposed between the source electrode and the drain electrode.

Exemplary embodiments of the present invention also disclose a method of manufacturing a display substrate. The method includes forming a gate electrode on a substrate, forming an oxide semiconductor layer on the gate electrode, forming an etch stop pattern on the gate electrode. The etch stop pattern includes a metal oxide. The method further includes forming a data metal layer on the etch stop pattern, patterning the oxide semiconductor layer and the data metal layer to form an oxide semiconductor pattern on the gate electrode, and to form a source electrode and a drain electrode on the oxide semiconductor pattern.

Exemplary embodiments of the present invention also disclose a method of manufacturing a display substrate. The method includes forming a first electrode on a substrate, forming an oxide semiconductor layer on the first electrode, forming a metal oxide layer on the oxide semiconductor layer, patterning the metal oxide layer to form a metal oxide layer pattern, forming a metal layer on the metal oxide layer pattern, and patterning the oxide semiconductor layer and the metal layer to form an oxide semiconductor pattern on the first electrode and a second electrode and a third electrode on the oxide semiconductor pattern.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention, and together with the description serve to explain the principles of the invention.

FIG. 1 is a plan view of a display substrate according to exemplary embodiments of the present invention.

FIG. 2 is a cross-sectional view of a display substrate taken along a line I-I′ of FIG. 1 according to exemplary embodiments of the present invention.

FIG. 3A, FIG. 3B, FIG. 3C, and FIG. 3D are cross sectional views of a method of manufacturing the display substrate of FIG. 1 according to exemplary embodiments of the present invention.

FIG. 4 is a plan view of a display substrate according to exemplary embodiments of the present invention.

FIG. 5 is a cross-sectional view of a display substrate taken along a line II-II′ of FIG. 4 according to exemplary embodiments of the present invention.

FIG. 6A, FIG. 6B, FIG. 6C, and FIG. 6D are cross sectional views illustrating a method of manufacturing the display substrate of FIG. 4 according to exemplary embodiments of the present invention.

### DETAILED DESCRIPTION OF THE ILLUSTRATED EMBODIMENTS

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present. It may also be understood that for the purposes of this disclosure, “at least one of X, Y, and Z” can be construed as X only, Y only, Z only, or any combination of two or more items X, Y, and Z (e.g., XYZ, XYY, YZ, ZZ).

Hereinafter, exemplary embodiments of the present invention are described in detail with reference to the accompanying drawings.

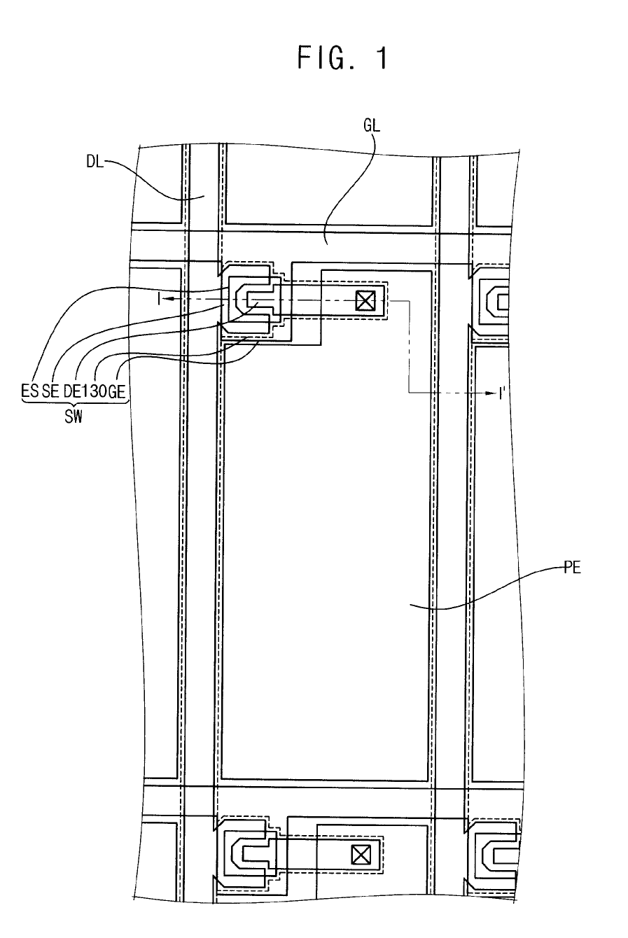

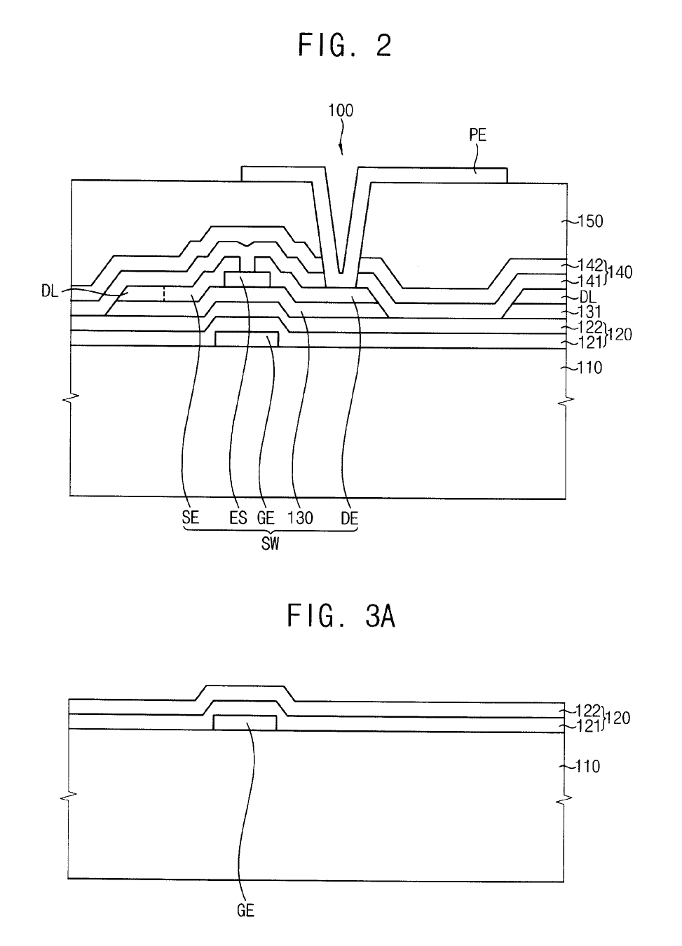

FIG. 1 is a plan view illustrating a display substrate according to exemplary embodiments of the present invention. FIG. 2 is a cross-sectional view illustrating a display substrate taken along a line I-I′ of FIG. 1.

Referring to FIG. 1 and FIG. 2, a display substrate 100 may include a base substrate 110, a gate electrode GE, a gate line GL, a gate insulating layer 120, a source electrode SE, a drain electrode DE, a data line DL, an oxide semiconductor pattern 130, an etch stop pattern ES, a protection layer 140, an organic layer 150 and a pixel electrode PE.

The gate electrode GE may be disposed on the base substrate 110. The gate line GL may be electrically connected to the gate electrode GE. Thus, the gate line GL may provide a gate driving signal to the gate electrode GE.

The gate electrode GE and the gate line GL may have a double-layered structure. For example, each of the gate electrode GE and the gate line GL may include a first layer including titanium (Ti) and a second layer including copper (Cu) disposed on the first layer. The first layer enhances adhesion between the second layer and the base substrate 110. The first layer may have a thickness of about 5000 Å (angstroms), and the second layer may have a thickness of about 300 Å. In some cases, each of the gate electrode GE and the gate line GL may have a single-layered structure including copper (Cu). In general, it should be understood that the gate electrode GE and the gate line GL may have any number of suitable layers made of one or more suitable materials, and that various thicknesses may be used for the first layer and the second layer of the gate electrode GE and the gate line GL.

The gate insulating layer 120 may be formed on the base substrate 110 and the gate electrode GE, and may protect the gate electrode GE and the gate line GL. The gate insulating layer 120 may include a first gate insulating layer 121 and a second gate insulating layer 122 formed on the first gate insulating layer 121. The first gate insulating layer 121 may include silicon nitride (SiNₓ), and may have a thickness of about 4000 Å. The second gate insulating layer 122 may include silicon oxide (SiOₓ), and may have a thickness of about 500 Å. “x” may be any real, positive number. In general, various suitable materials, thicknesses, and configurations may be used to form the first gate insulating layer 121 and the second gate insulating layer 122. In some cases, the gate insulating layer 120 may include only one of the first and second gate insulating layers 121 and 122. For example, the gate insulating layer 120 may include only the second gate insulating layer 122.

Each of the source electrode SE and the drain electrode DE may be disposed over the oxide semiconductor pattern 130 and the gate electrode GE, and may partially overlap the gate electrode GE. The drain electrode DE may be spaced apart from the source electrode SE to form a space between the source electrode SE and the drain electrode DE. The space may overlap the gate electrode GE. The data line DL may be connected to the source electrode SE. Thus, the data line DL may provide a data signal to the source electrode SE. Each of the source electrode SE, the drain electrode DE, and the data line DL may have the same layer structure as the gate electrode GE and the gate line GL. In some cases, each of the source electrode SE, the drain electrode DE, and the data line DL may include a first layer including copper (Cu) and a second layer including titanium (Ti). The first layer may have a thickness of about 5000 Å, and the second layer may have a thickness of about 300 Å. In some cases, each of the source electrode SE, the drain electrode DE, and the data line DL may have a single-layered structure including copper (Cu). In general, various suitable materials, thicknesses, and configurations may be used to form the source electrode SE, the drain electrode DE, and the data line DL.

The oxide semiconductor pattern 130 may be disposed on the second gate insulating layer 122 and over the gate electrode GE and the gate line GL. The oxide semiconductor pattern 130 may simultaneously be patterned with the source and drain electrodes SE and DE and the date line DL, so that the oxide semiconductor pattern 130 may be formed along the source and drain electrodes SE and DE and the data line DL. The oxide semiconductor pattern 130 corresponding to the source electrode SE and the oxide semiconductor pattern 130 corresponding to the drain electrode DE may not be separated from each other, and may be connected to each other in a continuous manner, so that the oxide semiconductor pattern 130 functions as a channel, through which electrons and holes flow between the source electrode SE and the drain electrode DE. The oxide semiconductor pattern 130 overlapping the space between the source electrode SE and the drain electrode DE may not be etched by using the etch stop pattern ES, so that the oxide semiconductor pattern 130 contacting the source electrode SE and the oxide semiconductor pattern 130 contacting the drain electrode DE may be connected to each other.

The oxide semiconductor pattern 130 may include gallium indium zinc oxide (GIZO). The oxide semiconductor pattern 130 may have any suitable thickness, including, for example, a thickness of about 400 Å.

The etch stop pattern ES may be disposed on a portion of the oxide semiconductor pattern 130 overlapping the gate electrode GE. The etch stop pattern ES may overlap a space between the source electrode SE and the drain electrode DE. Thus, the etch stop pattern ES may prevent the oxide semiconductor pattern 130 overlapping the space from being etched. The etch stop pattern ES may have a width smaller than that of the gate electrode GE, such that each of the source electrode SE and the drain electrode DE may partially overlap the gate electrode GE. The etch stop pattern ES may include a metal oxide (MₓO_{y}) where x and y are any positive, real numbers. Examples of the metal oxide (MₓO_{y}) may include, but are not limited to, aluminum oxide (Al₂O₃), titanium oxide (TiOₓ), titanium oxynitride (TiOₓN_{y}), gallium oxide (GaO), tantalum oxide (Ta₂O₃), yttrium oxide (Y₂O₃), manganese oxide (MnO), and tungsten oxide (WO₃). The etch stop pattern ES may have any suitable thickness, including, for example, about 300 Å to about 1000 Å.

The gate electrode GE, the source electrode SE, the drain electrode DE, the oxide semiconductor pattern 130, and the etch stop pattern ES may form a switching element SW of the display substrate 100.

The protection layer 140 may be disposed on the base substrate 110, on which the switching element SW is formed, and may protect the switching element SW. The protection layer 140 may include a first protection layer 141 and a second protection layer 142 formed on the first protection layer 141. The first protection layer 141 may include silicon oxide (SiOₓ), and may have a thickness of about 2000 Å. The second protection layer 142 may include silicon nitride (SiNₓ), and may have a thickness of about 1000 Å. In general, various suitable materials, thicknesses, and configurations may be used to form the first protection layer 141 and the second protection layer 142. In some cases, the protection layer 140 may include only one of the first protection layer 141 and the second protection layer 142. For example, the protection layer 140 may include only the first protection layer 141.

A lower surface of the oxide semiconductor pattern 130 may contact the second gate insulating layer 122, and a side surface of the oxide semiconductor pattern 130 may contact the first protection layer 141.

The organic layer 150 may be formed on the protection layer 140 to flatten a surface of the display substrate 100. Each of the protection layer 140 and the organic layer 150 may have a contact hole partially exposing the drain electrode DE.

The pixel electrode PE may be disposed on the organic layer 150, and electrically connected to the drain electrode DE via the contact hole. The pixel electrode PE may include a transparent conductive oxide (TCO). The TCO may include indium zinc oxide (IZO), indium tin oxide (ITO), and/or any other suitable material. The pixel electrode PE may have any suitable thickness including, for example, about 550 Å.

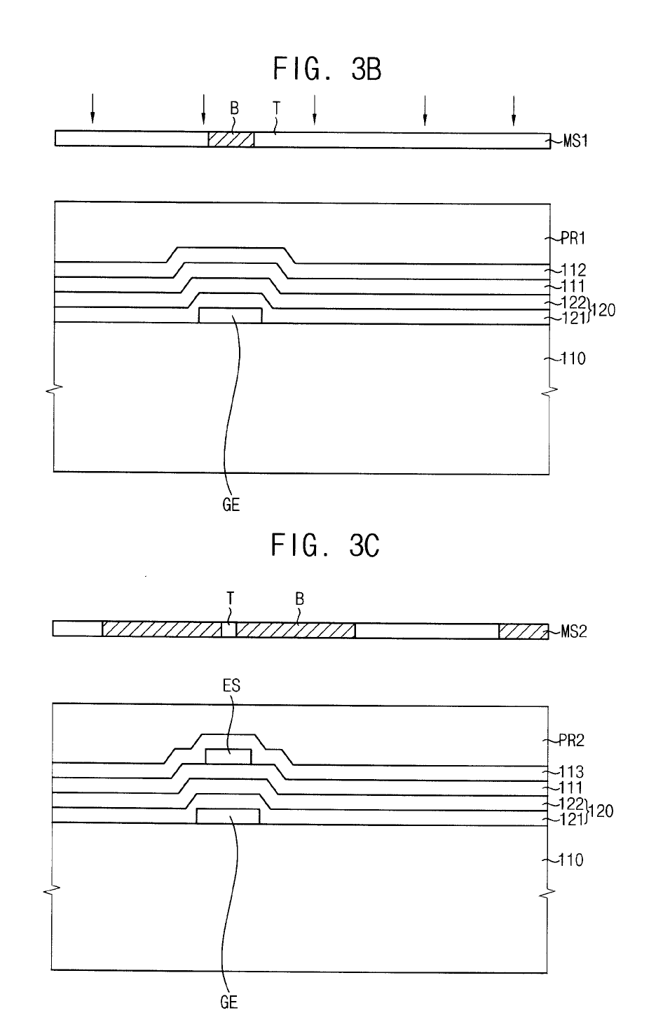

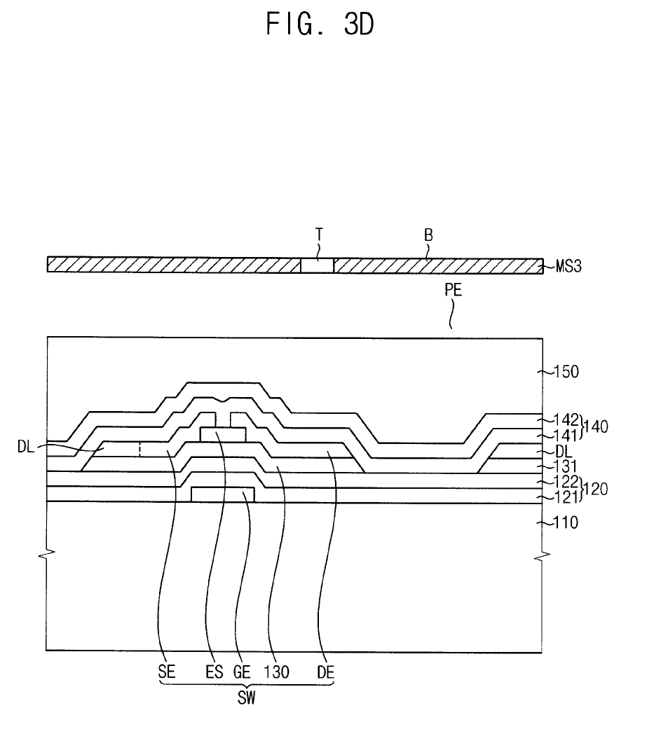

FIGS. 3A, 3B, 3C, and 3D are cross sectional views illustrating a method of manufacturing the display substrate of FIG. 1.

Referring to FIG. 3A, a gate metal layer may be deposited on the base substrate 110 through a sputter deposition method. For example, a first gate metal layer including titanium (Ti) and a second gate metal layer including copper (Cu) may sequentially be deposited on the base substrate 110. The first gate metal layer may be deposited at a thickness of about 300 Å, and the second gate metal layer may be deposited at a thickness of about 5000 Å. In general, the first gate metal layer and the second gate metal layer may have any suitable thickness, and may be composed of various suitable materials. The first gate metal layer may enhance adhesion between the second gate metal layer and the base substrate. The first and second gate metal layers may then be patterned using a first mask (not shown) and a first photoresist layer (not shown), so that a gate metal pattern including the gate electrode GE and the gate line GL may be formed. For example, the first and second gate metal layers may be wet-etched by trichloroethylene.

The gate insulating layer 120 may be deposited on the gate electrode GE and the gate line GL at about 370° C. through a chemical vapor deposition (CVD) method. For example, silicon nitride (SiNₓ) may be deposited on the base substrate 110, on which the gate electrode GE and the gate line GL are formed, through the CVD method, so that the first gate insulating layer 121 is formed. Silicon oxide (SiOₓ) may be deposited on the first gate insulating layer 121 through the CVD method, so that the second gate insulating layer 122 is formed. The first gate insulating layer 121 may be deposited with a thickness of about 4000 Å, and the second gate insulating layer 122 may be deposited with a thickness of about 500 Å. In general, various suitable materials, thicknesses, and configurations may be used to form the first gate insulating layer 121 and the second gate insulating layer 122.

Referring to FIG. 3B, the base substrate 110, on which the gate insulating layer 120 is formed, is put in a sputter chamber, and an oxide semiconductor layer 111 and an etch stop layer 112 may sequentially be sputter-deposited on the gate insulating layer 120. For example, the oxide semiconductor layer 111 may be sputter-deposited on the gate insulating layer 120, then the etch stop layer 112 may be sputter-deposited on the oxide semiconductor layer 111 in the sputter chamber without removing the substrate from the sputter chamber. The base substrate 110, on which the oxide semiconductor layer 111 is formed, is not taken out from the sputter chamber, so that there is no a vacuum break. Thus, the oxide semiconductor layer 111 is prevented from exposure to external environment and contamination, such that a backchannel interface state may be decreased.

The oxide semiconductor layer 111 may include gallium indium zinc oxide (GIZO), and may be deposited with a thickness of about 400 Å. The etch stop layer 112 may include a metal oxide (MₓO_{y}) where x and y are any positive, real numbers. Examples of the metal oxide (MₓO_{y}) may include, but are not limited to, aluminum oxide (Al₂O₃), titanium oxide (TiOₓ), titanium oxynitride (TiOₓN_{y}), gallium oxide (GaO), tantalum oxide (Ta₂O₃), yttrium oxide (Y₂O₃), manganese oxide (MnO), and tungsten oxide (WO₃). The etch stop layer 112 may be deposited with the thickness of about 300 Å to about 1000 Å.

A second photoresist layer PR1 may be deposited on the etch stop layer 112. The etch stop layer 112 may be patterned using the second photoresist layer PR1 and a second mask MS1 having a transmitting portion T and a blocking portion B to form the etch stop pattern ES. For example, in some cases, when the second photoresist layer PR1 includes a positive photosensitivity material, the etch stop layer 112, corresponding to the transmitting portion T, may be exposed to light to be dry-etched. In some cases, when the second photoresist layer PR1 includes a negative photosensitivity material, the etch stop layer 112 corresponding to the transmitting portion T is exposed to the light, so that the etch stop layer 112 corresponding to the blocking portion B may be dry-etched.

Referring to FIG. 3C, a data metal layer 113 is deposited on the etch stop pattern ES and the oxide semiconductor layer 111 using the sputter deposition method. For example, a first data metal layer including titanium (Ti) and a second data metal layer including copper (Cu) are sequentially deposited on the etch stop pattern ES and the oxide semiconductor layer 111. The first data metal layer may be deposited at a thickness of about 300 Å, and the second data metal layer may be deposited at a thickness of about 5000 Å. In general, the first data metal layer and the second data metal layer may have any suitable thickness. The first data metal layer may enhance adhesion between the second data metal layer and the oxide semiconductor pattern 130.

Thereafter, a third photoresist layer PR2 is deposited on the data metal layer 113. The oxide semiconductor layer 111 and the data metal layer 113 may be patterned. The data metal layer 113 may be patterned using the third photoresist layer PR2 and a third mask MS2 having a transmitting portion T and a blocking portion B. Thus, a data metal pattern including the data line DL, the source electrode SE and the drain electrode DE, and the oxide semiconductor pattern 130 overlapping the data metal pattern may be formed. The data metal layer 113 may be wet-etched by trichloroethylene.

The oxide semiconductor pattern 130 may be simultaneously patterned with the data metal pattern using the third mask MS2, so that the oxide semiconductor pattern 130 may be formed along the source electrode, the drain electrode DE, and the data line DL. The oxide semiconductor pattern 130 overlapping the etch stop pattern ES is prevented from being etched by the etch stop pattern ES, so that the oxide semiconductor pattern 130 overlapping the space between the source electrode SE and the drain electrode DE remains.

The oxide semiconductor pattern 130 is not formed before the etch stop pattern ES is formed, but may be formed with the data metal pattern after the etch stop pattern ES is formed. Thus, the oxide semiconductor pattern 130 may be prevented from being contaminated with a photosensitive material or an organic material by the etch stop pattern ES.

Referring to FIG. 3D, the protection layer 140 may be deposited on the oxide semiconductor pattern 130, the source electrode SE, and the drain electrode DE at about 280° C. through the CVD method. For example, silicon oxide (SiOx) may be deposited on the oxide semiconductor pattern 130 using the CVD method, so that the first protection layer 141 is formed. Silicon nitride (SiNₓ) is then deposited on the first protection layer 141 through the CVD method, so that the second protection layer 142 is formed. The first protection layer 141 may be deposited at a thickness of about 1000 Å, and the second protection layer 142 may be deposited at a thickness of about 2000 Å. In general, various suitable materials, thicknesses, and configurations may be used to form the first protection layer 141 and the second protection layer 142.

To improve reliability of the switching element SW including the gate electrode GE, the source electrode SE, and the drain electrode DE, the base substrate 110 on which the protection layer 140 is formed, is annealed at about 350° C. for about 1 hour. The organic layer 150 is then coated on the protection layer 140.

The protection layer 140 and the organic layer 150 are simultaneously patterned using a fourth mask MS3 having a transmitting portion T and a blocking portion B, so that the contact hole, partially exposing the drain electrode DE, is formed. The protecting layer 140 and the organic layer 150 may be dry-etched.

Referring to FIG. 2 again, a transparent electrode layer and a fourth photoresist layer are sequentially deposited on the organic layer 150, through which the contact hole is formed. For example, the transparent electrode layer may include a transparent conductive oxide (TCO). The TCO may include, but is not limited to, indium zinc oxide (IZO) and/or indium tin oxide (ITO). The transparent electrode layer may be deposited with the thickness of about 550 Å. The transparent electrode layer may be patterned using a fifth mask (not shown) and the fourth photoresist layer, so that the pixel electrode PE electrically connected to the drain electrode DE is formed.

Thus, the display substrate 100 including the gate metal pattern, the gate insulating layer 120, the oxide semiconductor pattern 130, the etch stop pattern ES, the data metal pattern, the protecting layer 140, the organic layer 150 and the pixel electrode PE may be formed.

According to exemplary embodiments of the present invention, the etch stop layer 112 may be sputter-deposited through the sputter deposition method, and the base substrate 110, on which the oxide semiconductor layer 111 is formed, may not be taken out from the sputter chamber, so that the oxide semiconductor pattern 130 may be prevented from being contaminated by impurities.

In addition, the oxide semiconductor layer 111 may simultaneously be patterned with the data metal layer 113. Thus, five masks are required, in total, for manufacturing the display substrate. The manufacturing process and the manufacturing cost may, therefore, be decreased.

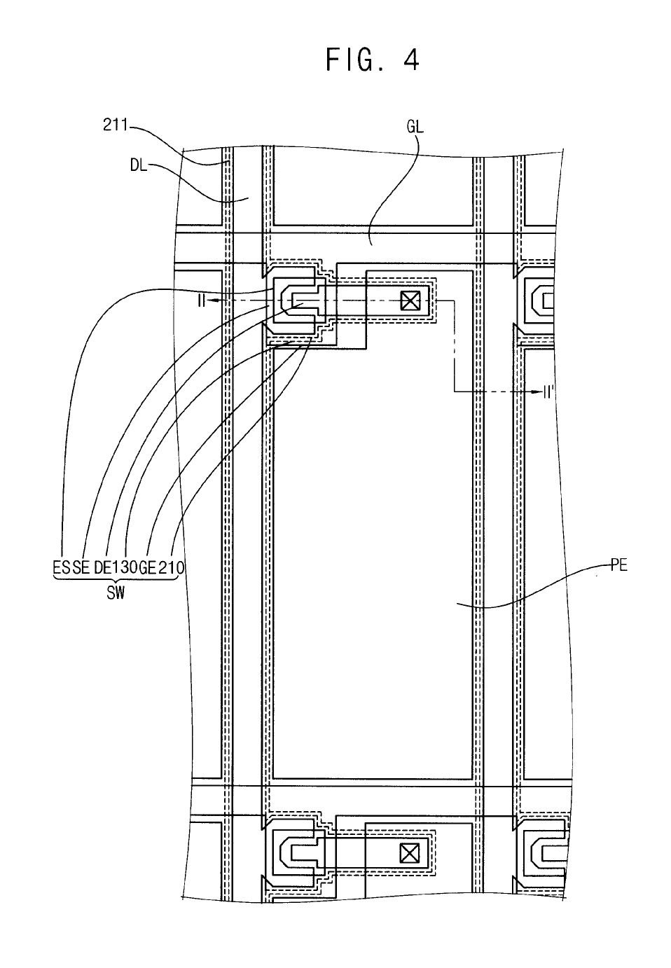

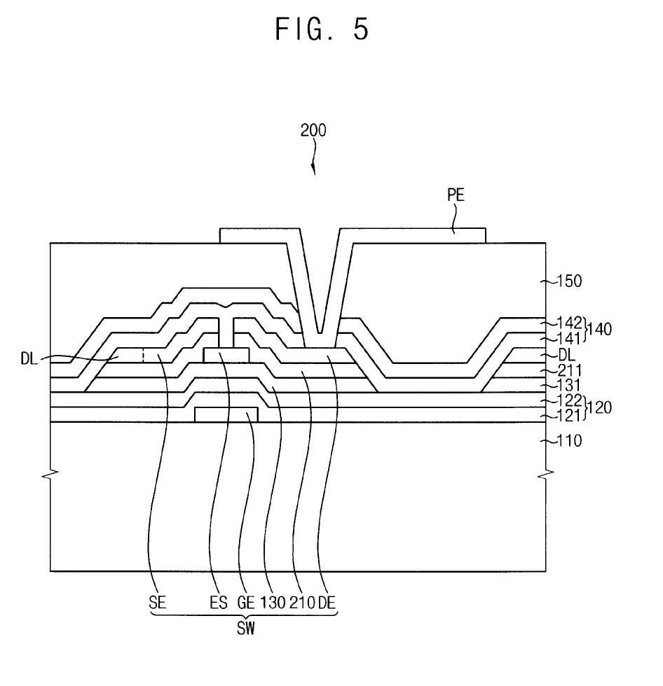

FIG. 4 is a plan view illustrating a display substrate according to exemplary embodiments of the present invention. FIG. 5 is a cross-sectional view illustrating a display substrate taken along a line II-II′ of FIG. 4.

The display substrate shown in FIG. 4 and FIG. 5 is substantially the same as the display substrate of FIG. 1 except for an ohmic contact pattern. The same reference numerals will be used to refer to the same or like parts as those described in the exemplary embodiments of FIG. 1 and any repetitive explanation will be omitted.

Referring to FIG. 4 and FIG. 5, a display substrate 200 may include a base substrate 110, a gate electrode GE, a gate line GL, a gate insulating layer 120, a source electrode SE, a drain electrode DE, a data line DL, an oxide semiconductor pattern 130, an etch stop pattern ES, a protection layer 140, an organic layer 150, a pixel electrode PE, and an ohmic contact pattern 210.

The ohmic contact pattern 210 may be disposed between the source and drain electrodes SE and DE and the oxide semiconductor pattern 130 and between the source and drain electrodes SE and DE and the etch stop pattern ES. The ohmic contact pattern 210 between the source and drain electrodes SE and DE and the oxide semiconductor pattern 130 may provide an ohmic contact between the source and drain electrodes SE and DE and the oxide semiconductor pattern 130. The ohmic contact pattern 210 may have a substantially same shape as the source and drain electrodes SE and DE in a plane view.

The ohmic contact pattern 210 may be disposed between the data line DL and the oxide semiconductor pattern 130 to provide the ohmic contact between the data line DL and the oxide semiconductor pattern 130. The ohmic contact pattern 210 may have substantially the same shape as the data line DL in a plane view.

The ohmic contact pattern 210 may be a transparent electrode including a tin oxide (SnOₓ) based compound or a zinc oxide (ZnOₓ) based compound. It should be understood, however, that the ohmic contact pattern 210 may be formed in any suitable shape using various suitable materials.

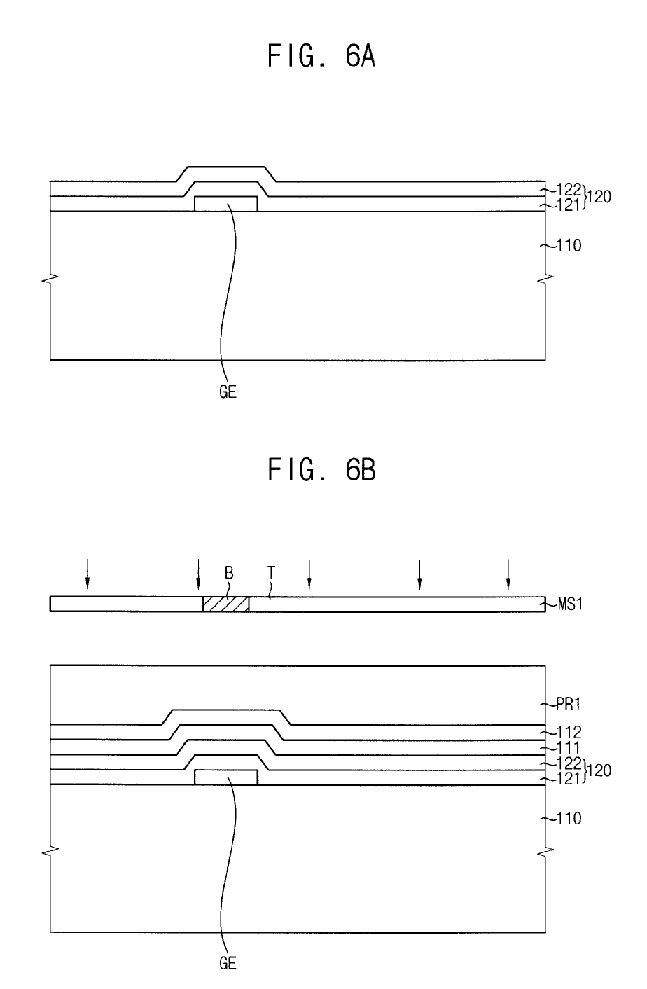

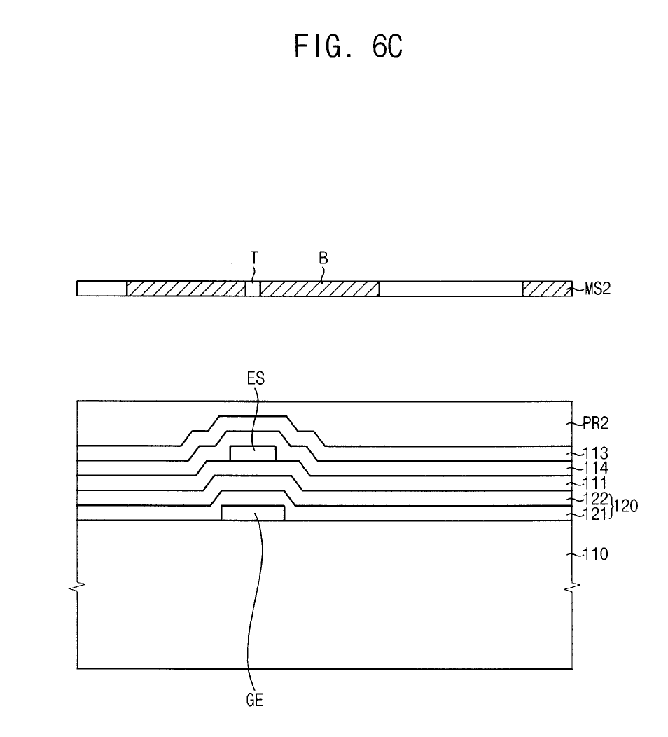

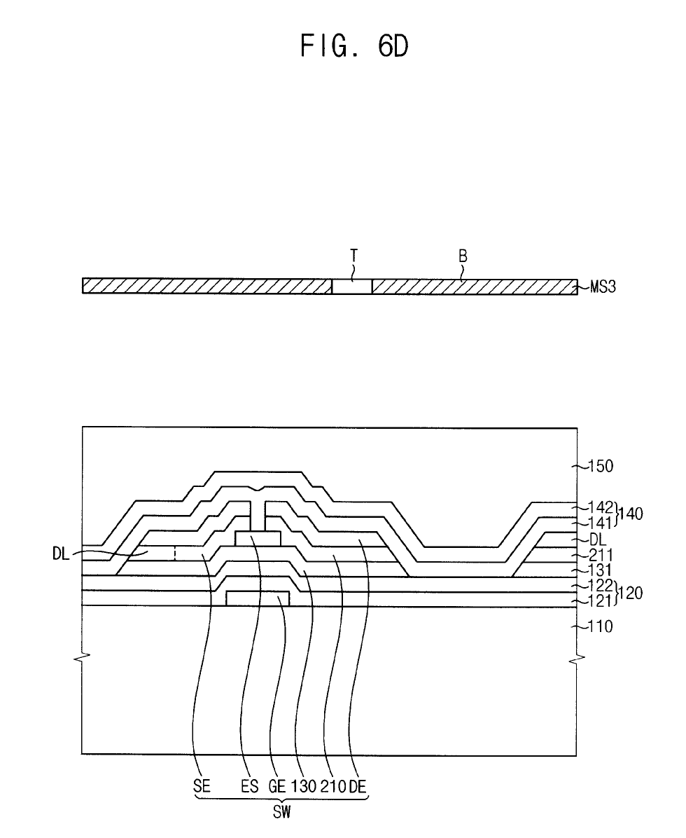

FIG. 6A, FIG. 6B, FIG. 6C, and FIG. 6D are cross sectional views illustrating a method of manufacturing the display substrate of FIG. 4 and FIG. 5.

The method of manufacturing the display substrate of FIG. 6A, FIG. 6B, FIG. 6C, and FIG. 6D is substantially the same as the method of manufacturing the display substrate of FIG. 3A, FIG. 3B, FIG. 3C, and FIG. 3D except for formation of an ohmic contact pattern. The same reference numerals will be used to refer to the same or like parts as those described in FIG. 3A, FIG. 3B, FIG. 3C, and FIG. 3D and any repetitive explanation will be omitted.

Referring to FIG. 6A, FIG. 6B, FIG. 6C, and FIG. 6D, a gate metal pattern including the gate electrode GE and the gate line GL may be formed on the base substrate 110. Then, the gate insulating layer 120, the oxide semiconductor layer 111, and the etch stop layer 112 may sequentially be deposited on the gate electrode GE and the gate line GL. For example, the oxide semiconductor layer 111 and the etch stop layer 112 may sequentially be deposited in the same chamber. The etch stop layer 112 may then be patterned, so that the etch stop pattern ES is formed.

Referring to FIG. 6C, an ohmic contact layer 114 and a data metal layer 113 may sequentially be deposited on the etch stop pattern ES. For example, the ohmic contact layer 114 may include a tin oxide (SnOₓ)-based compound or a zinc oxide (ZnOₓ)-based compound. In general, the ohmic contact layer 114 may be formed of any suitable material and may have any suitable thickness.

A third photoresist layer PR2 may be deposited on the data metal layer 113. The oxide semiconductor layer 111 may simultaneously be patterned, while the ohmic contact layer 114 and the data metal layer 113 may be patterned using the third photoresist layer PR2 and a third mask MS2 having a transmitting portion T and a blocking portion B. Thus, the data line DL, the source electrode SE, and the drain electrode DE, the ohmic contact pattern 210, and the oxide semiconductor pattern 130 may be formed.

The ohmic contact pattern 210 may simultaneously be patterned with the data metal pattern using the third mask MS2, so that the ohmic contact pattern 210 may be formed to have substantially the same shape as the drain electrode DE and source electrode SE.

Although the oxide semiconductor pattern 130 may simultaneously be patterned with the data metal pattern using the third mask MS2, the oxide semiconductor pattern 130 overlapping the etch stop pattern ES may not be etched by the etch stop pattern ES. Thus, the oxide semiconductor pattern 130 overlapping the space between the source electrode SE and the drain electrode DE may remain.

Therefore, the display substrate 200 including the gate metal pattern, the gate insulating layer 120, the data metal pattern, the oxide semiconductor pattern 130, the etch stop pattern ES, the ohmic contact pattern 210, the protecting layer 140, the organic layer 150 and the pixel electrode PE may be formed.

According to the exemplary embodiments of the present invention, the oxide semiconductor layer 111 and the ohmic contact layer 114 may simultaneously be patterned with the data metal layer 113, so that 5 masks are required in total for manufacturing the display substrate. Thus, the manufacturing process and the manufacturing cost may be decreased.

According to exemplary embodiments of the present invention, an etch stop layer may include a metal oxide, so that an oxide semiconductor layer and an etch stop layer may be sputter-deposited in the same chamber. Thus, there may be no vacuum break between the process of depositing the oxide semiconductor layer and the process of depositing the etch stop layer, so that the oxide semiconductor layer may be prevented from being contaminated by impurities. The reliability of the display substrate may, therefore, be improved.

The oxide semiconductor layer may simultaneously be patterned with the data metal layer using the same mask, so that the number of the processes and masks required for manufacturing the display substrate may be decreased. Thus, the manufacturing cost of the display substrate may be decreased.

It will be apparent to those skilled in the art that various modifications and variations can be made in the present invention without departing from the spirit or scope of the invention. Thus, it is intended that the present invention cover the modifications and variations of this invention provided they come within the scope of the appended claims and their equivalents.

What is claimed is:

1. A display substrate, comprising:
a gate electrode disposed on a base substrate;
an oxide semiconductor pattern disposed on the gate electrode;
a source electrode disposed on the oxide semiconductor pattern;
a drain electrode disposed on the oxide semiconductor pattern and spaced apart from the source electrode; and
an etch stop pattern comprising a metal oxide and disposed on the oxide semiconductor pattern, at least a part of the etch stop pattern being disposed between the source electrode and the drain electrode.

2. The display substrate of claim 1, wherein the metal oxide comprises at least one material selected from the group consisting of aluminum oxide (Al₂O₃), titanium oxide (TiOₓ), titanium oxynitride (TiOₓN_{y}), gallium oxide (GaO), tantalum oxide (Ta₂O₃), yttrium oxide (Y₂O₃), manganese oxide (MnO), and tungsten oxide (WO₃), wherein x and y are any positive, real number.

3. The display substrate of claim 1, further comprising an ohmic contact pattern disposed between the oxide semiconductor pattern and the source and drain electrodes.

4. The display substrate of claim 3, wherein the ohmic contact layer comprises a tin oxide-based compound or a zinc oxide-based compound.

5. The display substrate of claim 1, further comprising:
a gate insulating layer comprising silicon oxide, the gate insulating layer being disposed on the gate electrode; and
a protecting layer comprising silicon oxide, the protecting layer being disposed on the source electrode and the drain electrode.

6. The display substrate of claim 1, further comprising:
a gate insulating layer comprising:
a first gate insulating layer comprising silicon nitride, the first gate insulating layer disposed on the gate electrode; and
a second gate insulating layer comprising silicon oxide, the second gate insulating layer disposed on the first gate insulating layer; and
a protecting layer comprising:
a first protection layer comprising silicon oxide, the first protecting layer disposed on the source electrode and the drain electrode; and
a second protection layer comprising silicon nitride, the second protecting layer disposed on the first protection layer.

7. A method of manufacturing a display substrate, the method comprising:
forming a gate electrode on a substrate;
forming an oxide semiconductor layer on the gate electrode;
forming an etch stop pattern on the gate electrode, the etch stop pattern comprising a metal oxide;
forming a data metal layer on the etch stop pattern; and
patterning the oxide semiconductor layer and the data metal layer to form an oxide semiconductor pattern on the gate electrode, and to form a source electrode and a drain electrode on the oxide semiconductor pattern.

8. The method of claim 7, further comprising:
forming a gate insulating layer on the gate electrode, the gate insulating layer comprising silicon oxide.

9. The method of claim 8, wherein forming the gate insulating layer comprises:
forming a first gate insulating layer comprising silicon nitride, the first gate insulating layer being formed on the substrate; and
forming a second gate insulating layer comprising silicon oxide, the second gate insulating layer being formed on the first gate insulating layer.

10. The method of claim 9, wherein forming the oxide semiconductor layer comprises:
depositing the oxide semiconductor layer on the gate insulating layer using a sputter deposition method.

11. The method of claim 10, wherein forming the etch stop pattern comprises:
depositing an etch stop layer on the oxide semiconductor layer using a sputter deposition method; and
patterning the etch stop layer to form the etch stop pattern, at least a part of the etch stop pattern being disposed between the source electrode and the drain electrode.

12. The method of claim 7, further comprising:
forming an ohmic contact layer on the etch stop pattern

13. The method of claim 12, wherein forming the oxide semiconductor pattern, the source electrode, and the drain electrode comprise:
patterning the ohmic contact layer to form an ohmic contact pattern between the oxide semiconductor pattern and each of the source electrode and the drain electrode.

14. The method of claim 12, wherein the ohmic contact layer comprises a tin oxide-based compound or a zinc oxide-based compound.

15. The method of claim 7, further comprising:
forming a protecting layer comprising silicon oxide, the protecting layer being formed on the source electrode and the drain electrode;
forming an organic layer on the protecting layer;
patterning the protecting layer and the organic layer to form a contact hole partially exposing the drain electrode; and
forming a pixel electrode electrically connected to the drain electrode.

16. The method of claim 15, wherein forming the protecting layer comprises:
forming a first protection layer comprising silicon oxide, the first protection layer being formed on the source electrode and the drain electrode; and
forming a second protection layer comprising silicon nitride, the second protection layer being formed on the first protection layer.

17. The method of claim 15, further comprising:
annealing the base substrate on which the protecting layer is formed

18. The method of claim 7, wherein the metal oxide comprises at least one material selected from the group consisting of aluminum oxide (Al₂O₃), titanium oxide (TiOₓ), titanium oxynitride (TiOₓN_{y}), gallium oxide (GaO), tantalum oxide (Ta₂O₃), yttrium oxide (Y₂O₃), manganese oxide (MnO) and tungsten oxide (WO₃), where x and y are any positive, real numbers.

19. A method of manufacturing a display substrate, the method comprising:
forming a first electrode on a substrate;
forming an oxide semiconductor layer on the first electrode;
forming a metal oxide layer on the oxide semiconductor layer;
patterning the metal oxide layer to form a metal oxide layer pattern;
forming a metal layer on the metal oxide layer pattern; and
patterning the oxide semiconductor layer and the metal layer to form an oxide semiconductor pattern on the first electrode and a second electrode and a third electrode on the oxide semiconductor pattern.

20. The method of claim 19, wherein the oxide semiconductor layer and the metal oxide layer are both formed by sputtering, and the oxide semiconductor layer and the metal oxide layer are both formed in the same sputter chamber
